(19) United States
(12) Patent Application Publication
(10) Pub. No.: US 2025/0125151 A1
(43) Pub. Date: Apr. 17, 2025

(54) Electrolyte and Deposition of a Copper Barrier Layer in a Damascene Process

(71) Applicant: Element Solutions, Inc., Fort Lauderdale, FL (US)

(72) Inventors: Louis Caillard, Cachan (FR); Paul Blondeau, New Taipei City (TW)

(21) Appl. No.: 18/999,059

(22) Filed: Dec. 23, 2024

Related U.S. Application Data
(63) Continuation of application No. 18/016,409, filed on Jan. 16, 2023.

(30) Foreign Application Priority Data
Jul. 17, 2020 (FR) FR2007534

(51) Int. Cl. H01L 21/288; C25D 3/38; C25D 3/58; C25D 7/12; H01L 21/768; H01L 23/532

(52) U.S. Cl. CPC H01L 21/2885; C25D 3/38; C25D 3/58; C25D 7/123; H01L 21/76843; H01L 21/76864; H01L 21/76873; H01L 21/76877; H01L 23/53238

(57) ABSTRACT

The present invention relates to an electrolyte and its use in a process for fabricating copper interconnects. The electrolyte of pH greater than 6.0 comprises copper ions, manganese or zinc ions, and ethylenediamine which complexes the copper. A thin barrier layer is formed by annealing the deposited copper alloy, which causes manganese or zinc to migrate to the interface between the insulating dielectric material and the copper.

### TECHNICAL FIELD

The present invention relates to an electrolyte and its use for the electrodeposition of an alloy of copper and a second metal selected from manganese and zinc, on a conductive surface, in particular with a view to the formation of a wet barrier layer in a Damascene process.

The invention also relates to a manufacturing process that implements this electrolyte to create copper interconnects in integrated circuits.

### PRIOR ART

The Damascene process used to create conductive interconnects typically comprises:
depositing an insulating dielectric layer on silicon
etching the dielectric to form trenches
depositing a barrier layer or “liner” to prevent copper migration
depositing the copper, and
removing excess copper by chemical-mechanical polishing.

Copper can be deposited in a single step by filling the trenches directly on the barrier layer, or in two steps by depositing a thin layer (called a seed layer) on the barrier layer, followed by filling the trenches.

The barrier layer and the seed layer are usually deposited by physical vapor deposition (PVD) or chemical vapor deposition (CVD) processes. The filling can be carried out by dry process, although it is most often carried out by electrodeposition. Indeed, the deposits obtained by PVD are generally thicker on the protruding parts than in the hollows of the structures, so that the layers do not have a uniform thickness at all points of the substrate surface, which is desired to avoid. In addition, the most commonly used copper electrodeposition compositions are acidic in pH and generate a number of contaminants, including carbon, chlorine and sulfur, which cause reliability and current leakage problems due to their ability to move through the material under electric fields.

Finally, the fabrication of high-performance semiconductor integrated circuits requires a reduction in the size of the interconnects, so that the thickness of the seed layer and the thickness of the barrier layer must be considerably reduced to leave sufficient copper volume.

It is therefore desirable to have electrolytes that allow the deposition of very thin metal layers of regular thickness in order to guarantee the reliability of the devices.

There is also a need to provide electrolysis baths that lead to copper deposits with improved performance, i.e., with extremely low impurity contents, the formation rate of which is sufficiently high to make the manufacturing of electronic devices profitable, and allowing a reduction in the thickness of the barrier layers or even the elimination of the step of depositing a layer of a barrier material to the copper diffusion prior to the copper deposition step.

The inventors have found that an electrolyte with a pH greater than 6 obtained by dissolving a copper (II) salt, an organic zinc (II) salt and diethyleneamine in water achieves this result. The use of an organic manganese (II) salt instead of zinc gives an equivalent result.

The electrodeposition solution of the invention comprises copper ions and a doping element (zinc or manganese) which is co-deposited with the copper during electrolysis. The doping element, uniformly distributed in the deposited film, has the particular feature of migrating to one or more interfaces during a subsequent annealing step. The doping element has the particular feature of forming a barrier to the diffusion of copper for example, by aggregating with another metal (titanium or tantalum for example) or at the silicon oxide-metal interface.

The particular feature of this invention is that it can be used as a deposit on a filler layer, which makes it adaptable to multiple integrations. The doping element contained in the deposit migrates, during annealing, through the copper filler layer. The pure metal filler layer can be deposited by electrodeposition or by vapor deposition. In this case, the invention replaces the thick layer required for the chemical and mechanical polishing step. The invention is useful for reinforcing a copper diffusion barrier layer that is too thin or discontinuous, but also for creating an in situ diffusion barrier on a substrate that lacks one prior to the copper electrodeposition step.

The invention also creates thinner barrier layers and maximizes the space available for copper in small structures.

The possibility of forming a thin layer based on manganese or zinc without a physical or chemical deposition step prior to copper deposition has not been proposed until now. The invention very advantageously enables the deposition of manganese or zinc during the filling of the trenches.

### GENERAL DESCRIPTION OF THE INVENTION

Thus, the invention relates to an electrolyte for the electrodeposition of an alloy of copper and a metal selected from manganese and zinc, comprising in solution in water:
copper (II) ions in a molar concentration being between 1 mM and 120 mM;
a copper ion complexing agent selected from aliphatic polyamines having 2 to 4 amino groups, preferably ethylenediamine, in a molar concentration such that the ratio between the molar concentration of complexing agent and the molar concentration of copper ions ranges from 1:1 to 3:1;
ions of the metal selected from manganese and zinc in a molar concentration such that the ratio between the molar concentration of copper ions and the molar concentration of metal ranges from 1:10 to 10:1;
the electrolyte having a pH being between 6.0 and 10.0.

In the sense of the present description, the term “ranges from . . . to . . . ” or “is from . . . to . . . ” defines a range comprising a lower value and an upper value, as well as a range excluding a lower value and an upper value.

In the sense of the present description, the term “between . . . and . . . ” defines a range excluding a lower value and an upper value. For example, pH cannot be 6.0.

The electrolyte may additionally comprise thiodiglycolic acid in a concentration being between 1 and 500 mg/l, preferably between 1 mg/l and 100 mg/l.

The invention also relates to a copper deposition process implementing the electrolyte described above. This process comprises a first step of conformal deposition of a copper-metal alloy by electrolysis, and a second step of annealing the alloy to separate the metal (also called dopant metal) and the copper.

The concentration of impurities in the copper after annealing of the alloy can advantageously be less than 1000 atomic ppm.

The invention also has the advantage of creating conformal metal layers of very small thickness without the need for a dry process.

The electrolyte is preferably obtainable by dissolving a copper salt and an organic metal salt in water. The electrolyte is advantageously chlorine-free.

According to the process of the invention, a copper-manganese alloy or a copper-zinc alloy is deposited on the surface of a metallic material. The alloy is then heat treated to separate the copper from the dopant metal and to obtain a layer containing copper on the one hand and a layer containing manganese or zinc on the other. During the annealing of the alloy, the manganese or zinc atoms distributed in the alloy migrate to the interface between the metal layer and the insulating material to form a thin layer comprising manganese or zinc interposed between the metal layer and the insulating material. A stack of a layer of dielectric material, a layer comprising manganese or zinc, a thin metal layer and a copper deposit is thus obtained.

Finally, the process of the invention considerably reduces the thickness or even eliminates the deposition of a layer of a copper diffusion barrier material, such as tantalum nitride or titanium, between the dielectric and the copper.

The invention also relates to a Damascene process for fabricating copper interconnects in which the copper diffusion barrier layer comprises zinc or manganese deposited by an electrolytic process.

### DETAILED DESCRIPTION OF THE INVENTION

Thus, the invention relates to an electrolyte for the electrodeposition of an alloy of copper and a metal selected from manganese and zinc, comprising in solution in water:
copper (II) ions in a molar concentration being between 1 mM and 120 mM;
a copper (II) complexing agent selected from aliphatic polyamines having 2 to 4 amino groups, preferably ethylenediamine, in a molar concentration such that the ratio between the molar concentration of complexing agent and the molar concentration of copper ions ranges from 1:1 to 3:1;
metal ions in a molar concentration such that the ratio between the molar concentration of copper (II) ions and the molar concentration of metal is from 1:10 to 10:1;
the electrolyte having a pH being between 6.0 and 10.0.

“Electrodeposition” means here any process in which a substrate is electrically polarized and brought into contact with a liquid containing precursors of a metal in order to lead to the deposition of the metal on the surface of the substrate. Electrodeposition is performed by passing a current between the anode and the substrate to be coated, constituting the cathode, in an electrolyte containing metal ions.

According to a particular embodiment, the electrolyte is an electrolyte for the electrodeposition of an alloy of copper and manganese, comprising in solution in water:
copper (II) ions in a molar concentration being between 1 mM and 120 mM;
a copper complexing agent selected from aliphatic polyamines having 2 to 4 amino groups, preferably ethylenediamine, in a molar concentration such that the ratio between the molar concentration of complexing agent and the molar concentration of copper ions ranges from 1:1 to 3:1;
manganese ions in a molar concentration such that the ratio between the molar concentration of copper ions and the molar concentration of manganese is from 1:10 to 10:1;
the electrolyte having a pH being between 6.0 and 10.0.

According to another particular embodiment, the electrolyte is an electrolyte for the electrodeposition of an alloy of copper and zinc, comprising in solution in water:
copper (II) ions in a molar concentration being between 1 mM and 120 mM, copper ions being preferably obtained from dissolution of pentahydrated copper sulfate into water;
ethylenediamine in a molar concentration such that the ratio between the molar concentration of ethylenediamine and the molar concentration of copper ions ranges from 1.5 to 2.5, preferably from 1.8 and 2.2;
zinc ions in a molar concentration such that the ratio between the molar concentration of copper ions and the molar concentration of zinc ions is from 1:10 to 10:1, preferably from 1/1 to 5/1, zinc ions being preferably obtained by dissolution of zinc gluconate into water;
the electrolyte having a pH being between 6.0 and 10.0, preferably between 6.5 and 7.5, and still preferably between 6.8 and 7.2,
the electrolyte preferably comprising less than 0.01 g/L of a surfactant, and still preferably comprising no surfactant.

For example, in this embodiment, molar concentration of zinc ions is preferably being between 0.3 mM and 60 mM.

According to a particular embodiment, the electrolyte is obtainable by dissolving in water a copper (II) salt selected from copper sulfate, copper chloride, copper nitrate and copper acetate, preferably copper sulfate, and more preferably copper sulfate pentahydrate. The metal ions can be provided by dissolving an organic salt, preferably a carboxylic acid salt selected from gluconic acid, mucic acid, tartaric acid, citric acid and xylonic acid. The metal ions are preferably substantially complexed with the carboxylic acid or its carboxylate form in the electrolyte.

According to a particular feature, the copper ions are present within the electrodeposition composition in a concentration being between 1 mM and 120 mM, preferably between 10 mM and 100 mM, and more preferably between 40 mM and 90 mM.

The copper ion complexing agent consists of one or more compounds selected from aliphatic polyamines having from 2 to 4 amino groups (—NH2). Among the aliphatic polyamines that may be used, mention may be made of ethylenediamine, diethylenediamine, triethylenetetramine and dipropylenetriamine, preferably ethylenediamine.

The ratio between the molar concentration of complexing agent and the molar concentration of copper ions is being between 1:1 and 3:1, preferably 1.5 and 2.5, and more preferably between 1.8 and 2.2.

In the electrolyte, the copper ions are substantially in complex form with the complexing agent.

The metal ions are in a molar concentration such that the ratio between the molar concentration of copper and the molar concentration of metal ranges from 1:10 to 10:1.

In a particular embodiment of the invention, the metal is zinc. In this case, the ratio of the molar concentration of copper ions to the molar concentration of zinc ions is preferably from 1:1 to 10:1.

When the metal is manganese, the ratio between the molar concentration of copper and the molar concentration of manganese can range from 1:10 to 10:1.

The pH of the electrolyte of the invention is being between 6.0 and 10.0, more preferably between 6.5 and 10.0. According to a particular embodiment, the pH is being between 6.5 and 7.5, preferably between 6.8 and 7.2, for example equal to 7.0 at ready measurement uncertainties. The pH of the composition may optionally be adjusted to the desired range by means of one or more pH-modifying compounds, such as tetra-alkylammonium salts, for example tetra-methylammonium or tetra-ethylammonium. Tetra-ethylammonium hydroxide may be used.

Although there is no restriction in principle on the nature of the solvent (provided that it sufficiently solubilizes the active species in the solution and does not interfere with the electrodeposition), it will preferably be water. According to an embodiment, the solvent comprises mostly water by volume.

According to a particular embodiment, the composition contains between 40 mM and 90 mM copper sulfate, ethylenediamine in a molar ratio with copper being between 1.8 and 2.2, and zinc gluconate in a concentration such that the ratio between the molar concentration of copper and the molar concentration of zinc ranges from 2:1 to 3:1. Its pH is preferably of the order of 7, i.e. equal to 7.0 at ready measurement uncertainties.

### Electrochemical Process

The invention also relates to a process for depositing copper and a metal selected from manganese and zinc, comprising the following succession of steps:
a step of bringing a conductive surface into contact with an electrolyte in accordance with the above description,
a step of polarizing the conductive surface for a time sufficient to achieve simultaneous deposition of the copper and the metal, the copper and the metal being in the form of an alloy, and
a step of annealing the deposit of the alloy obtained at the end of the polarization step, said annealing being carried out at a temperature allowing the separation of the metal and the copper by migration of the metal toward the conductive surface.

The present invention therefore provides a method of manufacturing a seed layer of pure zinc that is located between silicon dioxide and pure copper, the method of manufacturing implementing deposition of zinc atoms by an electrochemical process.

The term “pure copper” means copper not containing any metal other than copper, in particular copper not containing zinc. In the sense of “pure zinc” is meant zinc which does not contain any metal other than zinc, in particular zinc which does not contain copper. The term “seed layer” is understood to mean a layer whose mean thickness is between 1 nm and 10 nm.

The method of the invention does not advantageously comprise a step of depositing a seed layer of an alloy of copper and zinc in a vapor phase, a vapor phase deposition step within the meaning of the invention being a physical deposition step carried out for example by PVD, CVD or ALD.

The deposition of the zinc atoms is preferably carried out, within the framework of the invention, in two steps: a first step of depositing a copper and zinc alloy by electroplating in order to obtain a copper-zinc deposit, said first step being followed by a second step of annealing this alloy in order to separate copper and zinc.

The copper-zinc deposit preferably has two possible forms. In a first form, the copper-zinc deposit fills trenches which have been processed from cavities previously etched in a semiconductor substrate, the trenches preferably having an opening width of less than 50 nm. In a second form, the copper-zinc deposit covers trenches containing copper and no zinc.

The manganese content or zinc content in the alloy deposited after the electrodeposition step is preferably being between 0.5 atomic % and 10 atomic %.

At the end of the annealing process, a first layer containing mainly metal, advantageously having a thickness being between 0.5 and 2 nm, and a second layer containing substantially copper can be formed.

According to an embodiment, the layer containing substantially copper is a layer consisting of copper and less than 1000 atomic ppm of impurities.

The polarization step is carried out for a sufficient time to form the desired alloy thickness. The conductive surface can be polarized either in galvanostatic mode (fixed imposed current), or in potentiostatic mode (imposed and fixed potential, optionally in relation to a reference electrode), or in pulsed mode (in current or in voltage).

In a preferred embodiment of the process of the invention, the conductive surface is that of a copper deposit.

The process of the invention can be used in two stages of a Damascene method.

In a first embodiment, the alloy is deposited to fill cavities that have been previously cut into the silicon and whose surface has been covered with a layer of a dielectric material (so-called “filling” mode) and then with a layer of a metallic material. In this first embodiment, the alloy is deposited on the conductive surface of the cavities.

In a second embodiment, the alloy is deposited on a cavity-filling copper layer (so-called “overburden” mode). The conductive surface is then the surface of a cavity-filling copper deposit, said deposit preferably comprising no metal other than zinc or manganese.

The cavities can have an average width being between 15 nm and 100 nm and an average depth being between 50 nm and 250 nm.

### Filling Mode

In the first embodiment, the process in accordance with the invention made it possible to produce copper fillings of excellent quality, without material defects and does not generate contaminants in significant amounts.

This process can be used to fill a cavity whose surface consists of a copper layer.

Advantageously, the process in accordance with the invention can also be implemented to fill a cavity whose conductive surface is that of a layer of copper diffusion barrier material. A copper diffusion barrier layer may comprise at least one of the materials selected from tantalum, titanium, tantalum nitride, titanium nitride, tungsten, tungsten titanate, and tungsten nitride.

The conductive surface can be that of a very thin metal layer covering the bottom and walls of cavities cut into the semiconductor substrate in a Damascene process. This metallic layer can be a copper seed layer, a layer of a copper diffusion barrier material, or a combination of both. The conductive surface may thus be the first surface of a metal layer having a thickness ranging from 1 nanometer to 10 nanometers, said metal layer having a second surface in contact with a layer of a dielectric material, such as silicon dioxide. The insulating dielectric layer can be inorganic (for example silicon oxide SiO2, silicon nitride SiN or aluminum oxide), deposited by CVD or otherwise, or organic (for example C N or D parylene, polyimide, benzocyclobutene, polybenzoxazole) deposited by liquid dipping or spin-on-glass (SOG) method.

The metal layer may comprise at least one material selected from the group consisting of cobalt, copper, tungsten, titanium, tantalum, ruthenium, nickel, titanium nitride, and tantalum nitride.

In a particular embodiment, the metal layer is a copper seed layer having a thickness ranging from 4 to 6 nanometers, or the assembly of a barrier layer having a thickness of about 1 nanometer and a copper seed layer having a thickness ranging from 4 to 6 nanometers.

### Overburden Mode

According to the second embodiment, the filling of the cavities with pure copper can be achieved by any method known to the person skilled in the art, whether by physical deposition (PVD, CVD, ALD), or by wet process (autocatalytic or electrolytic).

In the first case, the cavities will be filled with copper by PVD, more precisely by PVD reflow, commonly used for aggressive structures.

In a second case, the filling with copper is done by electrodeposition with an acid or alkaline electrolyte. It is preferred to use an electrolyte whose pH is greater than 6, to generate the lowest possible amount of contaminants. One such electrolyte is described for example in application WO 2015/086180.

### Electrical Step

The electrical step of the process of the invention may comprise a single or multiple polarization steps, the variables of which the person skilled in the art will know how to select on the basis of his or her general knowledge. The process in accordance with the invention can be carried out at a temperature being between 20° C. and 30° C.

The electrical step can be performed using at least one polarization mode selected from the group consisting of the ramp mode, the galvanostatic mode, and the galvanostatic pulsed mode.

According to an embodiment of the invention, the polarization of the conductive surface is performed in a pulsed mode by imposing a current per unit area in the range of 0.2 mA/cm² to 5 mA/cm² at a frequency ranging from 5 kHz to 15 kHz, and by exerting zero current periods at a frequency ranging from 1 kHz to 10 KHz.

The conductive surface of the substrate can be brought into contact with the electrolyte either before polarization or after polarization. It is preferred that the contact is made prior to energization.

The electrodeposition step is generally stopped when the alloy deposit covers the planar surface of the substrate to a thickness being between 50 nm and 400 nm, for example being between 125 nm and 300 nm. The alloy deposit corresponds to either the combination of the mass that is inside the cavities and the mass that covers the surface of the substrate, or the mass that covers a copper deposit made in an earlier step to fill the cavities.

The deposition rate of the copper alloy can be being between 0.1 nm/s and 3.0 nm/s, preferably between 1.0 nm/s and 3.0 nm/s, and more preferably between 1 nm/s and 2.5 nm/s.

### Annealing Step

The process of the invention comprises a step of annealing the deposit of the copper alloy obtained after the previously described electrodeposition.

This annealing heat treatment can be carried out at a temperature being between 50° C. and 550° C., preferably under reducing gas such as 4% H₂ in N₂.

A low impurity content combined with a very low percentage of voids results in a copper deposit with a lower resistivity.

During the annealing step, the manganese or zinc atoms in the alloy migrate to the surface of the conductive substrate, resulting in the formation of two layers: a first layer comprising substantially copper, and a second layer comprising substantially manganese or zinc.

In a first embodiment, the conductive surface with which the electrolyte is brought into contact is the surface of a metallic seed layer, which layer overlies an insulating dielectric material. In this embodiment, the manganese or zinc atoms migrate during the annealing step through the seed layer to reach the interface between the first seed layer and the insulating dielectric material.

In this first embodiment, the substrate may comprise a layer of a copper diffusion barrier material such as titanium or tantalum nitride, which is interposed between the insulating dielectric material and the metal seed layer.

In a second embodiment, the surface with which the electrolyte is brought into contact is the surface of a layer of a copper diffusion barrier material that overlies the insulating dielectric material. In this embodiment, the manganese or zinc atoms migrate during the annealing step through the layer of barrier material to reach the interface between the barrier layer and the insulating substrate.

The layer comprising substantially manganese or zinc is preferably a continuous layer with an average thickness ranging from 0.5 nm to 2 nm. “Continuous” means that the layer covers the entire surface of the dielectric substrate without leaving it flush. The thickness of the layer preferably varies by ±10% with respect to the average thickness.

The total impurity content of the copper deposit obtained by the electrodeposition and annealing process of the invention is less than 1000 atomic ppm, manganese or zinc not being considered impurities. The impurities are predominantly oxygen, followed by carbon and nitrogen. The total carbon and nitrogen content is less than 300 ppm.

The process of the invention may comprise a preliminary step of reducing plasma treatment in order to reduce the native metal oxide present on the surface of the substrate. The plasma also acts on the surface of the trenches to improve the quality of the interface between the conductive surface and the alloy. It is preferred that the subsequent electrodeposition step be performed immediately after the plasma treatment to minimize the reformation of native oxide.

### Damascene Process

The process of the invention can be used during the implementation of a so-called “Damascene” or “dual Damascene” integrated circuit manufacturing process.

In this case, the copper-filled cavities or cavities whose walls are covered with a layer of conductive material, which are brought into contact with the electrolyte, can be obtained in particular by carrying out the following steps:
a step of etching structures into a silicon substrate
a step of forming a silicon oxide layer on a silicon surface of the structures to obtain a silicon oxide surface,
a step of depositing a metal layer on said silicon oxide layer, so as to obtain a conductive surface of the cavities.

In a first embodiment, the metal layer consists of copper. In a second embodiment, the metal layer comprises a material having a copper diffusion barrier property. In a third embodiment, the metal layer comprises both copper and a material having a copper diffusion barrier property.

The metal layer can be deposited by any suitable method known to the skilled person. The copper interconnects obtained by the process of the invention may have an average width being between 15 nm and 100 nm and an average depth being between 50 nm and 250 nm.

The process described above makes it possible to obtain a semiconductor device with metallic interconnects comprising a layer of a dielectric material covered by and in contact with a layer comprising substantially manganese or zinc, which layer is covered by a layer of copper.

A seed layer of a metal may be interposed between the layer comprising substantially manganese or zinc, and the copper layer, and be in contact with both of these layers.

The interconnects are substantially made of copper and are obtainable by the process described above. In this case, they correspond to the copper deposit that fills the cavities. The interconnects can have an average width being between 15 nm and 100 nm and an average depth being between 50 nm and 250 nm.

The features which relate to the electrolyte and the process and which have been described above may be applied as appropriate to the semiconductor device of the invention.

The present invention will now be illustrated by the following non-limiting examples in which the compositions according to the invention are used to achieve copper filling or overburdening of narrow-width interconnect structures. In these examples, and unless otherwise indicated, the temperature is room temperature (being between 15° C. and 30° C.).

### Example 1: Electrodeposition of a Copper-Zinc Alloy to Fill Structures 40 nm Wide and 150 nm Deep

Trenches were filled by electrodeposition of a copper-zinc alloy, with the surface of the trenches covered with a copper seed layer. The deposition is done using a pH 7 composition containing a sulfur salt of copper (II) ions and an organic salt of zinc (II) ions in the presence of ethylene diamine.

### A.—Materials and Equipment:

### Substrate:

The substrate used in this example consisted of a 4×4 cm silicon coupon. The silicon is covered successively with silicon oxide and a 5 nm thick copper metal layer. The trenches to be filled are 40 nm wide and 150 nm deep. The measured resistivity of the substrate is about 30 ohm/square.

### Electrodeposition Solution:

In this solution, copper ions are supplied from 16 g/l CuSO4(H2O)5 (64 mM Cu2+) with two molar equivalents of ethylene diamine. Zinc ions are supplied from zinc gluconate to give a concentration of 25 mM Zn2+. Tetraethylammonium hydroxide (TEAH) is added to adjust the pH of the solution to 7.

### Equipment:

In this example, an electrodeposition apparatus was used consisting of two parts: the cell to hold the electrodeposition solution equipped with a fluid recirculation system to control the hydrodynamics of the system, and a rotating electrode equipped with a sample holder adapted to the size of the coupons used (4 cm×4 cm). The electrodeposition cell had two electrodes: a copper anode, and the silicon coupon coated with the copper metal layer constituted the cathode. The reference is connected to the anode. Connectors allowed the electrical contact of the electrodes which were connected by electric wires to a potentiostat supplying up to 20 V or 2 A.

### B.—Experimental Protocol:

### Preliminary Step:

The substrates generally do not require any particular treatment except if the layer of native copper oxide is too great because of the advanced age or poor storage of the wafers. This storage is normally done under nitrogen. In this case it is necessary to perform a plasma containing hydrogen. Either pure hydrogen or a gas mixture containing 4% hydrogen in nitrogen.

### Electrical Process:

The process is carried out as follows: the cathode was polarized in galvanostatic pulsed mode in a current range of 10 mA (or 1.4 mA/cm2) to 100 mA (or 14 mA/cm2), for example 50 mA (or 7.1 mA/cm2) with a pulse duration being between 5 and 1000 ms in cathodic polarization, and between 5 and 1000 ms in zero polarization between two cathodic pulses. This step was operated under a rotation of 60 rpm for 10 minutes.

### Annealing:

Annealing is performed at a temperature of 300° C. in a hydrogenated atmosphere (4% hydrogen in nitrogen) for 30 minutes, so as to induce zinc migration at the interface between SiO2 and copper.

### C—Results Obtained:

A transmission electron microscopy (TEM) analysis with 180 and 255k magnification, and with image in bright- and dark-field mode, performed after annealing, reveals a flawless filling of holes on the trench walls (sidewall voids) reflecting good copper nucleation and no holes in the structures (seam voids). The thick layer of copper on the structures is 200 nm. An XPS analysis before annealing shows the presence of zinc in the alloy of the order of 2 atomic % uniformly. The XPS analysis is performed by elemental analysis of Zn, copper and silicon on the surface before and after successive 1 to 10 nm argon beam etchings. The analysis gives a quantitative estimation of the elements present on the surface and on the first 10 nanometers in depth. The source used is monochromatic Al-Kα X-Ray (1486.6 eV). The analyzed samples are cut in 1 cm×1 cm.

This same type of analysis, after annealing, shows on the one hand the migration of zinc both toward the SiO2-copper interface and toward the extreme surface. On the other hand, the total contamination in oxygen, carbon and nitrogen, measured by XPS analysis under the conditions described above, does not exceed 600 atomic ppm.

### Example 2: Electrodeposition of a Copper-Zinc Alloy on Structures Previously Filled with Copper by PVD

A thick layer of a copper-zinc alloy was deposited by electrodeposition on a previously dry-filled pure copper deposit to fill trenches 16 nm wide and 150 nm deep. The electrodeposition is done using a pH 7 composition containing a sulfur salt of copper (II) ions and an organic salt of zinc (II) ions in the presence of ethylene diamine.

The substrate used in this example was a 4×4 cm silicon coupon. The silicon is coated with silicon oxide and a 1 nm thick titanium bonding layer.

1. Dry Filling of Structures with Copper:

The trenches, 16 nm wide and 150 nm deep, were filled with pure copper using a standard pure copper deposition technique. In this example, the PVD reflow deposition technique, commonly used in the semiconductor industry for aggressive structures, was used. A copper layer that fills the trenches and is 10 nm thick above the trenches is obtained.

### 2. Electrodeposition to Deposit the Copper-Zinc Alloy:

The electrodeposition solution used is the same as in Example 1, and the equipment used is the same as in Example 1.

### Experimental Protocol:

### Preliminary Step:

Substrates generally do not require any special treatment.

### Electrical Process for Alloy Deposition:

The process is performed as in Example 1.

### Annealing:

Annealing is performed at a temperature of 300° C. in a hydrogenated atmosphere (4% hydrogen in nitrogen) for 30 minutes, so as to induce zinc migration at the interface between the titanium and the copper.

### Results Obtained:

The thick copper layer on the structures is 200 nm. An XPS analysis before annealing shows the presence of zinc in the alloy of the order of 2 atomic % uniformly in the layer. The same type of analysis, after annealing, shows on the one hand the migration of zinc both toward the extreme surface and toward the titanium-copper interface, thus highlighting the diffusion through the pure copper previously deposited by dry process. On the other hand, the total contamination in oxygen, carbon and nitrogen does not exceed 600 atomic ppm.

### Example 3: Electrodeposition of a Copper-Zinc Alloy on Structures Previously Filled with Copper by an Electrolytic Process

Trenches 16 nm wide and 150 nm deep were filled with pure copper by an electrolytic process and then a thick layer of a copper-zinc alloy was deposited on the copper by electrodeposition. The electrodeposition of the alloy is done using a pH 7 composition containing a sulfur salt of copper (II) ions and an organic salt of zinc (II) ions in the presence of ethylene diamine.

The substrate used in this example was a 4×4 cm silicon coupon. The silicon is coated with silicon oxide, a 1 nm thick titanium primer and a 5 nm copper seed layer deposited by copper PVD.

In a first step, the trenches, 16 nm wide and 150 nm deep, were filled with pure copper by electrolysis.

### 1. Filling of the Structures:

The filling of the structures is performed electrolytically with solutions specialized in filling aggressive structures (<20 nm opening).

### Electrodeposition Solution:

In this solution, the concentration of 2,2′-bipyridine was 4.55 mM and the concentration of imidazole was 4.55 mM. The concentration of CuSO₄(H₂O)₅ was equal to 1.3 g/l, which is equivalent to 4.55 mM. The concentration of thiodiglycolic acid was equal to 10 ppm. The concentration of tetramethylammonium sulfate was equal to 3.45 g/l (14 mM). The pH of the solution was being between 6.7 and 7.2.

### Equipment:

The equipment used in this example was identical to that used in Example 1.

### Experimental Protocol

The cathode was polarized in pulse mode with a current of 7.5 mA (or 0.94 mA/cm2) with a pulse frequency of 10 KHz for the cathode pulse and 5 kHz for the rest periods between two cathode pulses. The duration of the electrodeposition step was 8 min to obtain a complete filling of the trenches and the covering of the substrate surface to a thickness of 10 nm.

In a second step, a copper-zinc alloy was deposited on the pure copper.

### 2. Copper-Zinc Alloy Deposition on Copper-Filled Trenches

### Electrodeposition Solution:

The electrodeposition solution used is the same as in Example 1.

### Equipment:

The equipment used is the same as in Example 1.

### Electrical Process for Alloy Deposition:

The process is identical to that of Example 1.

### 3. Annealing:

Annealing is performed at a temperature of 300° C. in a hydrogenated atmosphere (4% hydrogen in nitrogen) for 30 minutes, so as to induce zinc migration at the interface between the titanium and the copper.

### Results Obtained:

The thick copper layer on the structures is 200 nm. An XPS analysis before annealing shows the presence of zinc in the alloy of the order of 2 atomic % uniformly in the layer. The same type of analysis, after annealing, shows on the one hand the migration of zinc both toward the extreme surface and toward the titanium-copper interface, thus highlighting the diffusion through the pure copper previously electroplated. On the other hand, the total contamination in oxygen, carbon and nitrogen does not exceed 600 atomic ppm.

### Example 4: Electrodeposition of a Copper-Zinc Alloy to Fill 40 nm Wide and 150 nm Deep Structures

Trenches were filled by electrodeposition of a copper-zinc alloy on a copper seed layer. The deposition is done using a pH 7 composition containing a sulfur salt of copper (II) ions and an organic salt of zinc (II) ions in the presence of ethylene diamine.

### A.—Materials and Equipment:

### Substrate:

The substrate used in this example consisted of a 4×4 cm silicon coupon. The silicon is covered with silicon oxide coated and in contact with a 1 nm TaN copper diffusion barrier layer, covered with 5 nm copper metal. The trenches to be filled are therefore 40 nm wide and 150 nm deep. The measured resistivity of the substrate is roughly 30 ohm/square.

### Electrodeposition Solution:

The solution is identical to that of Example 1.

### Equipment:

The equipment used is the same as in Example 1.

### B.—Experimental Protocol:

### Preliminary Step:

Substrates generally do not require any particular treatment except if the layer of native copper oxide is too great because of the advanced age or poor storage of the wafers. This storage is normally done under nitrogen. In this case it is necessary to perform a plasma containing hydrogen. Either pure hydrogen or a gas mixture containing 4% hydrogen in nitrogen.

### Electrical Process for Alloy Deposition:

The process is identical to that of Example 1.

### Annealing:

Annealing is carried out at a temperature of 300° C. under a hydrogenated atmosphere (4% hydrogen in nitrogen) for 30 minutes, so as to cause the migration of zinc to silicon dioxide.

### C—Results Obtained:

A transmission electron microscopy (TEM) analysis, carried out after annealing, reveals a flawless filling of holes on the trench walls (sidewall voids), indicating good copper nucleation, and no holes in the structures (seam voids). The thick layer of copper on the structures is 200 nm. An XPS analysis before annealing shows the presence of zinc in the alloy of the order of 2 atomic %, uniformly. The same type of analysis, after annealing, shows on the one hand the migration of zinc both toward the TaN-copper interface and toward the extreme surface. On the other hand, the total contamination of the copper deposit in oxygen, carbon and nitrogen does not exceed 600 atomic ppm.

1. An electrolyte for the electrodeposition of an alloy comprising copper and a metal selected from manganese and zinc, said electrolyte comprising in solution in water:
copper (II) ions in a molar concentration being between 1 mM and 120 mM;
a copper (II) ion complexing agent selected from aliphatic polyamines having 2 to 4 amino groups, in a molar concentration such that the ratio between the molar concentration of complexing agent and the molar concentration of copper (II) ions ranges from 1:1 to 3:1;
ions of the metal selected from manganese and zinc in a molar concentration such that the ratio between the molar concentration of copper ions and the molar concentration of metal ions ranges from 1:10 to 10:1;
the electrolyte having a pH being between 6.5 and 7.5.

2. The electrolyte as claimed in claim 12, wherein the pH is between 6.8 and 7.2.

3. The electrolyte as claimed in claim 12, wherein the ratio between the molar concentration of complexing agent and the molar concentration of copper ions is between 1.8 and 2.2.

4. The electrolyte as claimed in claim 1, wherein the metal is zinc.

5. the electrolyte as claimed in claim 1, wherein the ratio between the molar concentration of copper ions and the molar concentration of zinc ions ranges from 1:1 to 10:1.

6. A process for depositing copper and a metal selected from manganese and zinc, said process comprising the following sequence of steps:
a step of bringing a conductive surface into contact with an electrolyte according to claim 12,
a step of polarizing the conductive surface for a time sufficient to achieve simultaneous deposition of the copper and the metal, the copper and the metal being in the form of an alloy, and
a step of annealing the alloy obtained at the end of the polarization step, said annealing being carried out at a temperature allowing the separation of the metal and the copper by migration of the metal toward the conductive surface.

7. The process as claimed in claim 6, wherein the conductive surface is a first surface of a metal layer having a thickness ranging from 1 nanometer to 10 nanometers, said metal layer having a second surface in contact with an insulating dielectric material.

8. The process as claimed in claim 6, wherein the metal layer comprises at least one material selected from the group consisting of cobalt, copper, tungsten, titanium, tantalum, ruthenium, nickel, titanium nitride, and tantalum nitride.

9. The process as claimed in claim 6, wherein the conductive surface is a conductive surface of cavities.

10. The process as claimed in claim 6, wherein the conductive surface is the surface of a cavity-filling copper deposit.

11. The process as claimed in claim 9, wherein the cavities have an average width being between 15 nm and 100 nm and an average depth being between 50 nm and 250 nm.

12. An electrolyte for the electrodeposition of an alloy comprising copper and a manganese, said electrolyte comprising in solution in water:
copper (II) ions in a molar concentration being between 1 mM and 120 mM;
a copper (II) ion complexing agent selected from aliphatic polyamines having 2 to 4 amino groups, in a molar concentration such that the ratio between the molar concentration of complexing agent and the molar concentration of copper (II) ions ranges from 1:1 to 3:1;
manganese ions in a molar concentration such that the ratio between the molar concentration of copper ions and the molar concentration of manganese ions ranges from 1:10 to 10:1;
the electrolyte having a pH being between 6.5 and 7.5; and
the electrolyte is free of chloride ions.

13. The electrolyte as claimed in claim 12, wherein the aliphatic polyamines are selected from the group consisting of ethylenediamine, diethylenediamine, triethylenetetramine, and dipropylenetriamine, and combinations thereof.

14. The electrolyte as claimed in claim 13, wherein at least one of the aliphatic polyamines is ethylenediamine.

15. The electrolyte as claimed in claim 12, wherein the aliphatic polyamines comprise two or more compounds selected from the group consisting of ethylenediamine, diethylenediamine, triethylenetetramine, and dipropylenetriamine.

16. The electrolyte as claimed in claim 15, wherein one of the two or more compounds is ethylenediamine.

17. The electrolyte as claimed in claim 12, wherein the electrolyte is at least substantially free of a surfactant.
